(19) United States
(12) Patent Application Publication
(10) Pub. No.: US 2014/0315342 A1
(43) Pub. Date: Oct. 23, 2014

(54) DEPOSITION APPARATUS, DEPOSITION METHOD, ORGANIC EL DISPLAY, AND LIGHTING DEVICE

(71) Applicants: Tomohiko Edura, Sendai-shi (JP); Chihaya Adachi, Fukuoka (JP); Shigeyuki Matsunami, Fukuoka (JP)

(72) Inventors: Tomohiko Edura, Sendai-shi (JP); Chihaya Adachi, Fukuoka (JP); Shigeyuki Matsunami, Fukuoka (JP)

(73) Assignees: KYUSHU UNIVERISTY, NATIONAL UNIVERSITY CORPORATION, Fukuoka-shi, Fukuoka (JP); TOKYO ELECTRON LIMITED, Tokyo (JP)

(21) Appl. No.: 14/002,386

(22) PCT Filed: Mar. 2, 2012
(86) PCT No.: PCT/JP2012/055445

§ 371 Date: Aug. 30, 2013

(30) Foreign Application Priority Data
Mar. 3, 2011 (JP) 2011-046438

(51) Int. Cl. H01L 51/00

(52) U.S. Cl. CPC H01L 51/0008
USPC 438/46

(57) ABSTRACT

A deposition method includes moving a substrate in a first direction within a processing chamber; generating a first source gas by evaporating a first film forming source material; discharging the first source gas from a first discharge opening toward the substrate being moved in the processing chamber; forming a first line-shaped thin film elongated in the first direction by depositing the first source gas on the substrate; generating a second source gas by evaporating a second film forming source material; discharging the second source gas from a second discharge opening offset from the first discharge opening in a second direction, which intersects the first direction, toward the substrate being moved in the processing chamber; and forming a second line-shaped thin film elongated in the first direction by depositing the second source gas on the substrate at a position spaced apart from the first line-shaped thin film.

### TECHNICAL FIELD

The embodiments described herein pertain generally to a deposition technique for depositing a thin film of a film forming material on a substrate by evaporating the film forming material; and, more particularly, the embodiments pertain to a deposition apparatus and a deposition method for forming a line-shaped thin film pattern and also pertain to an organic EL display and a lighting device.

### BACKGROUND ART

Recently, an organic EL (Electroluminescence) display is attracting high attention as a next-generation flat panel display (FPD). Especially, the organic EL display is self-luminous and, thus, does not require a backlight. Thus, it is easy to manufacture a thin film type light-weighted organic EL display. Further, the organic EL display also has highly advantageous characteristics with respect to viewing angle, contrast, response speed, power consumption and flexibility. For the reasons to be mentioned below, however, there has been problems in scaling up the organic EL device and improving productivity thereof.

The principle of light emission of organic EL is as follows. Power is supplied to a light emitting layer made of an organic material and sandwiched between two sheets of electrodes (anode and cathode). That is, holes are injected into the light emitting layer from the anode while concurrently electrons are injected into the light emitting layer from the cathode. The injected holes and electrons are recombined in the light emitting layer (i.e., excites the light emitting layer). When the light emitting layer returns back into a base state from this excited state, the light emitting layer emits light.

Conventionally, in the organic EL display, as one of light emission methods for displaying full-color images, there has been known a juxtaposed arrangement where pixels of three primary colors (i.e., R (Red), G (Green) and B (Blue)) are arranged side by side. In this juxtaposed arrangement, light emitting layers of R, G and B colors are selectively deposited on a substrate, respectively. A mask deposition method is a current mainstream film forming method for performing the selective deposition of the light emitting layers of the respective colors.

In the mask deposition method, deposition is performed using a metal mask, i.e., a so-called shadow mask, having openings at positions corresponding to positions of the substrate where a film forming material is supposed to be deposited. That is, a shadow mask is placed in front of the substrate, and a film forming material is deposited on the substrate through the openings of the shadow mask. In the aforementioned juxtaposed arrangement of the color pixels, since patterns of the light emitting layers of R, G and B colors are all same, the light emitting layers of R, G and B colors can be selectively deposited by the deposition method while moving a single shadow mask in parallel with the substrate.

Patent Document 1: Japanese Patent Laid-open Publication No. 2005-325425

### DISCLOSURE OF THE INVENTION

### Problems to be Solved by the Invention

The mask deposition method, however, has many drawbacks, imposing limitations in the manufacture of the organic EL display.

The shadow mask especially involves many problems. A high-precision shadow mask is of a very high price. Further, organic materials for use in forming the light emitting layers of R, G and B colors are also of a very high price. On the other hand, since a ratio of the area of the openings of the shadow mask to the total area of the mask is small, majority of evaporated materials (generally, no smaller than about 95%) may adhere to the mask. Thus, a ratio of the evaporated materials that is deposited on the substrate as a light emitting layer, i.e., a utilization efficiency of the organic material barely reaches 5%.

Further, the alignment (position adjustment) of the shadow mask needs to be performed with a very high level of precision. For example, if the alignment is not performed accurately, an R light emitting layer and a G light emitting layer would be overlapped, so that a production yield is reduced. Meanwhile, since heat is radiated from a high-temperature gas heated and evaporated during a film forming process, the shadow mask may be thermally expanded. Therefore, although the alignment is performed accurately, there may be generated an error in mask accuracy (e.g., alignment error, dimension error of an opening pattern, etc.). Furthermore, a friction between a rear surface of the shadow mask and a front surface of the substrate may cause a scratch on a thin film (light emitting layer) on the substrate.

In addition, in the mask deposition method, deposition of each of the R, G and B colors is performed on the entire surface of the substrate through the mask. Thus, in order to improve a throughput as much as possible in this deposition method, an individual film forming chamber (processing chamber) needs to be prepared for each of the R, G and B colors, and the substrate is transferred between the film forming chambers for the respective colors in sequence along with the shadow mask. Materials deposited on the shadow mask, however, may be separated from the shadow mask during the transfer or alignment, so that particle may be generated.

Furthermore, preparing the individual film forming chamber for each of the R, G and B colors is a great disadvantage in space efficiency (footprint) of an organic EL display manufacturing apparatus or cost competitiveness. Further, in a typical organic EL, not only light emitting layers but also various kinds of organic thin films such as an electron transport layer, a hole transport layer, an electron injection layer and a hole injection layer are interposed between an anode and a cathode. When the selective deposition of each of the R, G and B light emitting layers is performed by the mask deposition method, individual film forming chambers need to be provided for each of these organic thin films as in the aforementioned case of forming the respective light emitting layers in order to improve a throughput. Accordingly, the problems of the large footprint or the high cost are getting more serious in an actual manufacturing apparatus.

Besides, other problems are also raised by using the shadow mask. For example, when a substrate is bend due to its self-weight, it is likely that the substrate may come into contact with the shadow mask (thus, it is difficult to hold the substrate in widely used face-down method in a deposition process). Further, cleaning of the shadow mask is very troublesome. Generally, as a size of a screen of the organic EL display is increased, the shadow mask is also scaled up. Thus, the aforementioned problems regarding the shadow mask become conspicuous.

As stated above, the mask deposition method using the shadow mask has many difficulties in increasing the size of the screen of the organic EL display and improving the production yield thereof.

In view of the foregoing problems, example embodiments provide a deposition apparatus and a deposition method of depositing a multiple number of line-shaped thin films on a substrate selectively and efficiently without using a shadow mask.

### Means for Solving the Problems

A deposition apparatus in accordance with an example embodiment includes a processing chamber configured to accommodate a processing target substrate therein; a moving device configured to move the substrate in a first direction within the processing chamber; a first evaporation source configured to generate a first source gas by evaporating a first film forming source material; a first nozzle, having a first discharge opening, configured to receive the first source gas from the first evaporation source and discharge the first source gas from the first discharge opening toward the substrate being moved within the processing chamber; a second evaporation source configured to generate a second source gas by evaporating a second film forming source material; and a second nozzle, having a second discharge opening offset from the first discharge opening in a second direction that intersects the first direction, configured to receive the second source gas from the second evaporation source and discharge the second source gas from the second discharge opening toward the substrate being moved within the processing chamber. Further, the first source gas is deposited on the substrate to form a first line-shaped thin film elongated in the first direction, and the second source gas is deposited on the substrate to form a second line-shaped thin film elongated in the first direction at a position spaced apart from the first line-shaped thin film.

In the deposition apparatus having the above-described configuration, by discharging the first source gas and the second source gas to the substrate from the first nozzle and the second nozzle while moving the substrate in the first direction only one time within the processing chamber, it is possible to form the first thin film and the second thin film on the line on the substrate while separating them appropriately, i.e., by selectively depositing them, without using a shadow mask.

In accordance with a first aspect of an example embodiment, a deposition method includes moving a substrate in a first direction within a processing chamber; generating a first source gas by evaporating a first film forming source material; discharging the first source gas from a first discharge opening toward the substrate being moved in the processing chamber; forming a first line-shaped thin film elongated in the first direction by depositing the first source gas on the substrate; generating a second source gas by evaporating a second film forming source material; discharging the second source gas from a second discharge opening offset from the first discharge opening in a second direction, which intersects the first direction, toward the substrate being moved in the processing chamber; and forming a second line-shaped thin film elongated in the first direction by depositing the second source gas on the substrate at a position spaced apart from the first line-shaped thin film.

By the deposition method in accordance with the first aspect of the example embodiment, by discharging the first source gas and the second source gas to the substrate from the first nozzle and the second nozzle while moving the substrate in the first direction only one time within the processing chamber, it is possible to form the first line-shaped thin film and the second line-shaped thin film on the substrate while separating them appropriately, i.e., by selectively depositing them, without using a shadow mask.

In accordance with a second aspect of the example embodiment, a deposition method includes moving a substrate in a first direction within a processing chamber; generating a first source gas by evaporating a first film forming source material; discharging the first source gas from a first discharge opening toward the substrate being moved in the processing chamber; forming a first line-shaped thin film elongated in the first direction by depositing the first source gas on the substrate; generating a second source gas by evaporating a second film forming source material; discharging the second source gas from the second discharge opening offset from the first discharge opening in a second direction, which intersects the first direction, toward the substrate being moved in the processing chamber; forming a second line-shaped thin film elongated in the first direction by depositing the second source gas on the substrate at a position spaced apart from the first line-shaped thin film; generating a third source gas by generating a third film forming source material; discharging the third source gas from a third discharge opening offset from the first discharge opening and the second discharge opening in the second direction, which intersects the first direction, toward the substrate being moved in the processing chamber: and forming a third line-shaped thin film elongated in the first direction by depositing the third source gas on the substrate at a position spaced apart from the first line-shaped thin film and the second line-shaped thin film.

By the deposition method in accordance with the second aspect of the example embodiment, by discharging the first source gas, the second source gas and the third source gas to the substrate from the first nozzle, the second nozzle and the third nozzle while moving the substrate in the first direction only one time within the processing chamber, it is possible to form the first thin film, the second thin film and the third thin film on a line on the substrate while separating them appropriately, i.e., by selectively depositing them, without using a shadow mask.

In accordance with a third aspect of the example embodiment, a deposition method includes moving a substrate in a first direction within a processing chamber; generating a first source gas by evaporating a first film forming source material; discharging the first source gas from a first discharge opening toward the substrate being moved in the processing chamber; forming a first line-shaped thin film elongated in the first direction by depositing the first source gas on the substrate; generating a second source gas by evaporating a second film forming source material; discharging the second source gas from a second discharge opening offset from the first discharge opening in a second direction, which intersects the first direction, toward the substrate being moved in the processing chamber; forming a second line-shaped thin film elongated in the first direction by depositing the second source gas on the substrate at a position spaced apart from the first line-shaped thin film; generating a third source gas by generating a third film forming source material; discharging the third source gas, toward the substrate being moved in the processing chamber, from a third discharge opening offset from the first discharge opening and the second discharge opening in the first direction toward a downstream side of a substrate moving direction; and forming a first plane-shaped thin film by depositing the third source gas on the first line-shaped thin film and the second line-shaped thin film on the substrate.

By the deposition method in accordance with the third aspect of the example embodiment, by discharging the first source gas, the second source gas and the third source gas to the substrate from the first nozzle, the second nozzle and the third nozzle while moving the substrate in the first direction only one time within the processing chamber, it is possible to form the first thin film and the second thin film on a line on the substrate while separating them appropriately, i.e., by selectively depositing them and, also, possible to fill a space between the first thin film and the second thin film on a line and to form a first plane-shaped thin film covering the first line-shaped thin film and the second line-shaped thin film, without using a shadow mask.

In accordance with a fourth aspect of the example embodiment, a deposition method includes moving a substrate in a first direction within a processing chamber; generating a first source gas by evaporating a first film forming source material; discharging the first source gas from a first discharge opening toward the substrate being moved in the processing chamber; forming a first line-shaped thin film elongated in the first direction by depositing the first source gas on the substrate; generating a second source gas by evaporating a second film forming source material; discharging the second source gas from a second discharge opening offset from the first discharge opening in a second direction, which intersects the first direction, toward the substrate being moved in the processing chamber; forming a second line-shaped thin film elongated in the first direction by depositing the second source gas on the substrate at a position spaced apart from the first line-shaped thin film; generating a third source gas by generating a third film forming source material; discharging the third source gas, toward the substrate being moved in the processing chamber, from a third discharge opening offset from the first discharge opening and the second discharge opening in the first direction toward an upstream side of a substrate moving direction: and forming a first plane-shaped thin film by depositing the third source gas on the substrate before the first line-shaped thin film and the second line-shaped thin film are formed.

By the deposition method in accordance with the fourth aspect of the example embodiment, by discharging the first source gas, the second source gas and the third source gas to the substrate from the first nozzle, the second nozzle and the third nozzle while moving the substrate in the first direction only one time within the processing chamber, it is possible to form the first thin film and the second thin film on a line on the substrate while separating them appropriately, i.e., by selectively depositing them and, also, possible to form a first plane-shaped thin film as a base layer of the first thin film and the second thin film on a line.

### Effect of the Invention

By using the deposition apparatus and the deposition method in accordance with the example embodiments, it may be possible to selectively deposit a multiple number of line-shaped thin films on a substrate efficiently without using a shadow mask.

### BRIEF DESCRIPTION OF THE DRAWINGS

FIG. 1 is a diagram illustrating an overall configuration of a deposition apparatus in accordance with an example embodiment.

FIG. 2 is a diagram illustrating a configuration of a major component (source gas discharging unit) of the deposition apparatus.

FIG. 3A is a diagram for describing a cosine method used in a layout design of a discharge opening in accordance with the example embodiment.

FIG. 3B is a diagram for describing the cosine method.

FIG. 4 is a side view illustrating a configuration and an operation of the source gas discharging unit of the deposition apparatus.

FIG. 5 is a perspective view illustrating formation of juxtaposed R, G and B light emitting layers (line-shaped thin films) in the deposition apparatus.

FIG. 6 provides a plane view illustrating formation of juxtaposed R, G and B light emitting layers (line-shaped thin films) and patterns thereof in the deposition apparatus.

FIG. 7 provides a longitudinal cross sectional view illustrating an example structure of an organic EL color display device to which the example embodiment is applicable.

FIG. 8 is a perspective view illustrating an example where a passive matrix type driving method is applied to the device structure of FIG. 7 in accordance with the example embodiment.

FIG. 9 is a perspective view illustrating a modification example of a discharge opening of a nozzle for forming a line-shaped thin film.

FIG. 10 is a plane view illustrating formation of juxtaposed R, G and B light emitting layers (line-shaped thin films) and patterns thereof in the modification example of FIG. 9.

FIG. 11 is a perspective view illustrating another modification example of a discharge opening of a nozzle for forming a line-shaped thin film.

FIG. 12 is a plane view illustrating still another modification example of a discharge opening of a nozzle for forming a line-shaped thin film.

FIG. 13 is a plane view illustrating still another modification example of a discharge opening of a nozzle for forming a plane-shaped thin film.

FIG. 14 is a longitudinal cross sectional view illustrating another example structure of an organic EL color display device to which the example embodiment is applicable.

FIG. 15 is a perspective view illustrating a modification example of a source gas discharging unit suitable for forming the device structure of FIG. 14.

FIG. 16 is a side view illustrating a configuration and an operation of the source gas discharging unit of FIG. 15.

FIG. 17A is a partially enlarged cross sectional view illustrating a modification example where a heat insulating plate is attached to a nozzle.

FIG. 17B is a partially enlarged cross sectional view illustrating another modification example where a heat insulating plate is attached to a nozzle.

FIG. 18A is a cross sectional view illustrating an example device structure where respective colors of light emitting layers are isolated by banks (partition walls).

FIG. 18B is a cross sectional view illustrating another example device structure where respective colors of light emitting layers are isolated by banks (partition walls).

### MODE FOR CARRYING OUT THE INVENTION

In the following, example embodiments will be described, and reference is made to the accompanying drawings, which form a part of the description.

A deposition apparatus in accordance with an example embodiment is used when depositing and forming plural kinds of organic material layers including a light emitting layer on a transparent substrate, e.g., a glass substrate in the manufacture process of, e.g., an organic EL color display.

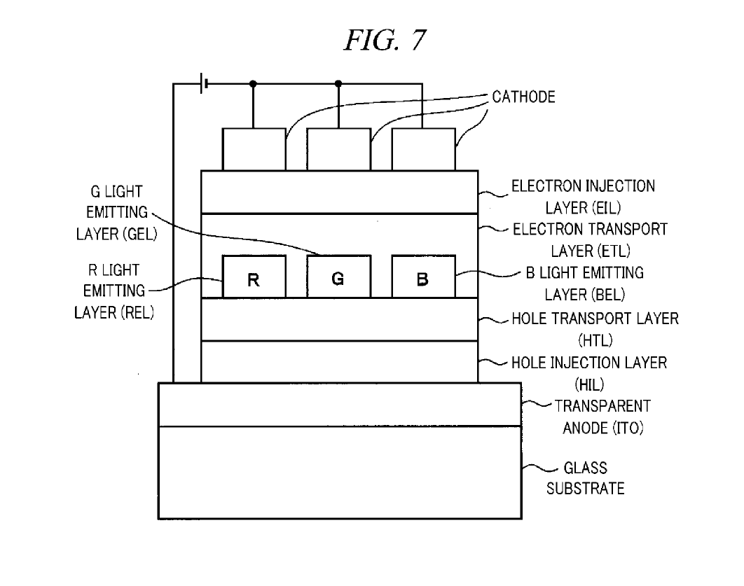

As one example of such an organic EL color display, as illustrated in FIG. 7, there is known a device structure where a transparent anode, a hole injection layer (HIL), a hole transport layer (HTL), juxtaposed R, G and B light emitting layers (REL, GEL and BEL), an electron transport layer (ETL), an electron injection layer (EIL) and a cathode are deposited on a glass substrate S in sequence. In the manufacture of this device, the deposition apparatus in accordance with the present example embodiment may form a total of 7 different kinds of thin films including the hole injection layer (HIL), the hole transport layer (HTL), the R, G and B light emitting layers (REL, GEL and BEL), the electron transport layer (ETL) and the electron injection layer (EIL) in a single processing chamber through a single deposition process. In this case, the transparent anode may be made of, but not limited to, ITO (Indium Tin Oxide) and is formed through a pre-process by another film forming apparatus, such as a sputtering apparatus. Further, the cathode may be made of, but not limited to, an aluminum alloy and is formed through a post-process by another film forming apparatus, such as a sputtering apparatus.

[Apparatus Configuration of Example Embodiment]

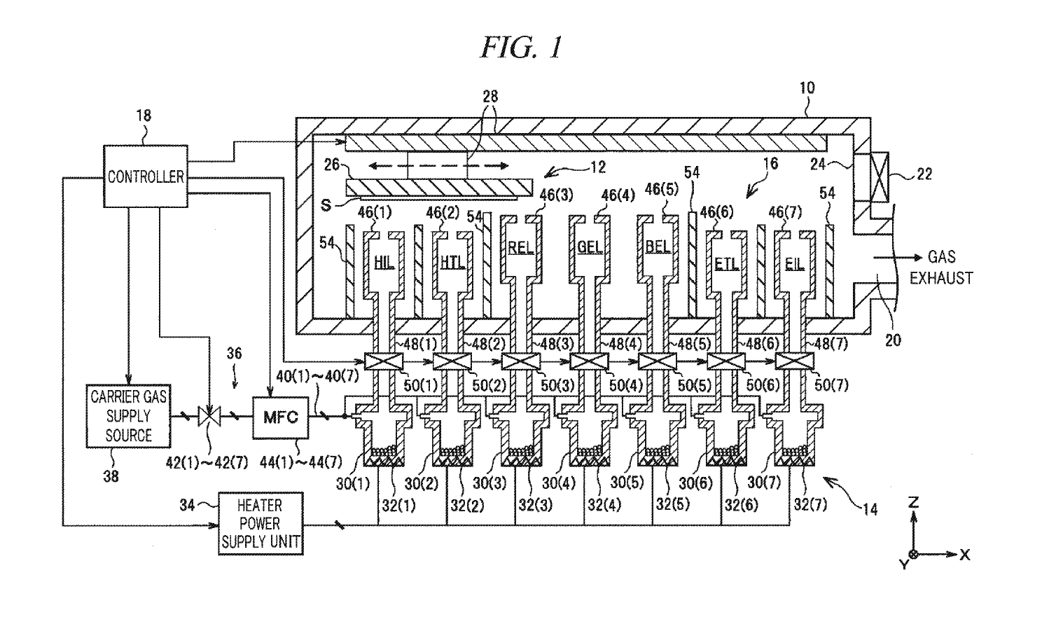

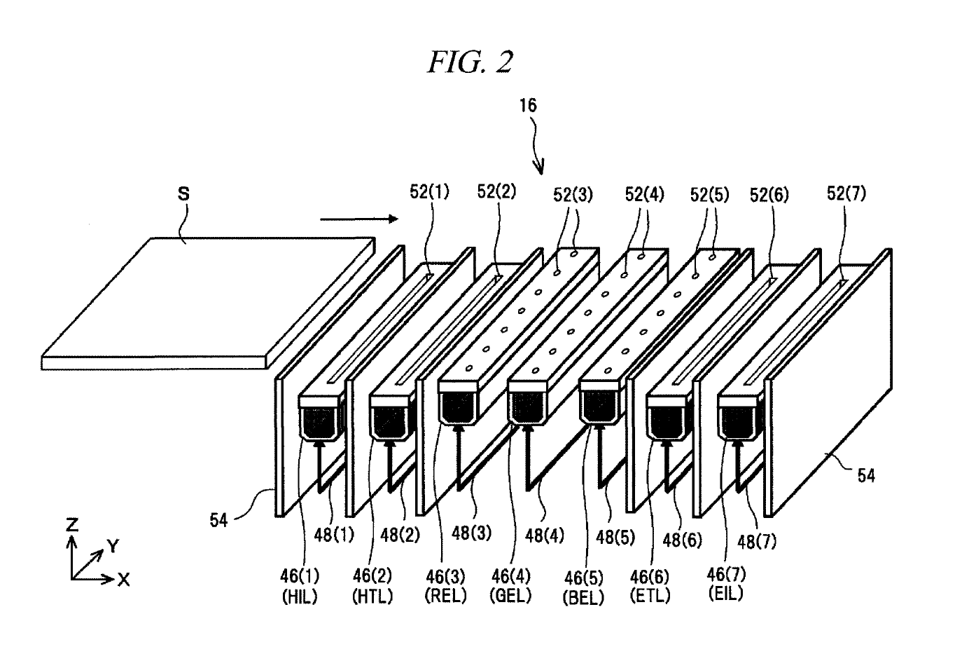

FIG. 1 illustrates a configuration of the deposition apparatus in accordance with the example embodiment. FIG. 2 illustrates a configuration of a major component (source gas discharging unit) of this deposition apparatus.

As depicted in FIG. 1, this deposition apparatus includes, basically, a processing chamber (chamber) 10 that accommodates therein a glass substrate S to be processed; a moving device 12 configured to hold the substrate S thereon and move the substrate S in one direction (X direction); an evaporating device 14 configured to generate source gases by evaporating source materials or film forming materials of the plural kinds (7 kinds) of organic material layers individually; a source gas discharging unit 16 configured to receive the plural kinds (7 kinds) of source gases from the evaporating device 14 and discharge the source gases toward the substrate S which is being moved; and a controller 18 configured to control the overall status, mode and operation of the apparatus and the statuses, modes and operations of the individual components of the apparatus.

The processing chamber 10 is configured to be evacuable and is connected to a gas exhaust device (not shown) such as a vacuum pump or the like through a gas exhaust opening 20 formed in a sidewall or a bottom surface of the processing chamber 10. An opening 24, through which the substrate is loaded and unloaded, is also formed in the sidewall of the processing chamber 10, and the opening 24 is opened or closed by a gate valve 22.

The moving device 12 includes a substrate holding table or stage 26 that holds thereon the substrate S in a face-down manner (i.e., with a processing target surface of the substrate facing downward); and a scanning unit 28 coupled to the stage 26 and configured to slide along the ceiling of the processing chamber 10 in X direction at a constant speed. A high-voltage DC power supply (not shown) is electrically connected to the stage 26 via a switch, and an electrostatic chuck (not shown) that detachably holds the substrate S thereon by an electrostatic attractive force is embedded in the stage 26. Further, the stage 26 is also equipped with a temperature control device configured to cool the substrate S to a required temperature. In general, a coolant path is formed within the stage 26, and a cooling water of a preset temperature is circulated through and supplied in the coolant path from a chiller unit (not shown) provided outside. The scanning unit 28 includes, but not limited to, a linear motor (not shown) as a driving member for sliding motion.

The evaporating device 14 includes a multiple number of evaporation sources 30(1) to 30(7). The number of the evaporation sources 30(1) to 30(7) corresponds to the number of the kinds of the thin films formed on the substrate S in this deposition apparatus, i.e., seven. Here, the HIL evaporation source 30(1) generates a HIL source gas by heating and evaporating, in, e.g., a furnace, an organic film forming material which is a source material of the hole injection layer (HIL). The HTL evaporation source 30(2) generates a HTL source gas by heating and evaporating, in a furnace, an organic film forming material which is a source material of the hole transport layer (HTL).

Further, the REL evaporation source 30(3) generates a REL source gas by heating and evaporating, in a furnace, an organic film forming material which is a source material of the R light emitting layer (REL). The GEL evaporation source 30(4) generates a GEL source gas by heating and evaporating, in a furnace, an organic film forming material which is a source material of the G light emitting layer (GEL). The BEL evaporation source 30(5) generates a BEL source gas by heating and evaporating, in a furnace, an organic film forming material which is a source material of the B light emitting layer (BEL).

The ETL evaporation source 30(6) generates an ETL source gas by heating and generating, in a furnace, an organic film forming material which is a source material of the electron transport layer (ETL). The EIL evaporation source 30(7) generates an EIL source gas by heating and evaporating, in a furnace, an organic film forming material which is a source material of the electron injection layer (EIL).

As heaters configured to heat the film forming materials, the evaporation sources 30(1) to 30(7) includes resistance heating members 32(1) to 32(7) embedded or provided in the furnaces, respectively. Each of the resistance heating members 32(1) to 32(7) may be made of, by way of example, but not limitation, a high melting point material. A heater power supply unit 34 is configured to supply electric currents to the respective resistance heating members 32(1) to 32(7) individually and, thus, control heating temperatures (e.g., about 200° C. to about 500° C.) in the respective evaporation sources 30(1) to 30(7) independently.

The evaporating device 14 includes a carrier gas supply device 36 configured to supply a carrier gas. The sources gases generated in the respective evaporation sources 30(1) to 30(7) are transferred to the source gas discharging unit 16 while mixed with the carrier gas. The carrier gas supply device 36 includes a carrier gas supply source 38 configured to store therein an inert gas (e.g., an argon gas, a helium gas, a krypton gas or a nitrogen gas) as a carrier gas; a multiple number of (seven) gas lines 40(1) to 40(7) that connects the carrier gas supply source 38 to the evaporation sources 30(1) to 30(7), respectively; and a multiple number of (seven) opening/closing valves 42(1) to 42(7) and mass flow controllers (MFC) 44(1) to 44(7) provided on the gas lines 40(1) to 40(7), respectively. The mass flow controller (MFC) 44(1) to 44(7) are configured to control pressures or flow rates of the carrier gases flowing in the gas lines 40(1) to 40(7), respectively, under the control of the controller 18.

The source gas discharging unit 16 includes, within the processing chamber 10, a multiple number of (seven) nozzles 46(1) to 46(7) corresponding to the multiple number of (seven) evaporation sources 30(1) to 30(7). All of these nozzles 46(1) to 46(7) are of elongated shapes and are arranged side by side in a single row along a scanning direction (X direction). Each of the nozzles 46(1) to 46(7) is elongated in a horizontal direction (Y direction) orthogonal to the scanning direction (X direction). The source gases are discharged upward from discharge openings formed in top surfaces of the respective nozzles 46(1) to 46(7).

Here, the HIL nozzle 46(1) is connected to the HIL evaporation source 30(1) via a gas line 48(1) that penetrates a bottom wall of the processing chamber 10 and is located at the most upstream position that is closest to a start position of substrate scanning or deposition scanning by the moving device 12. The HTL nozzle 46(2) is connected to the HTL evaporation source 30(2) via a gas line 48(2) that penetrates the bottom wall of the processing chamber 10 and is located at the second position in the sequence of the deposition scanning, i.e., at a position near the downstream side than the HIL nozzle 46(1).

Further, the REL nozzle 46(3) is connected to the REL evaporation source 30(3) via a gas line 48(3) that penetrates the bottom wall of the processing chamber 10 and is provided at the third position in the sequence of the deposition scanning, i.e., at a position near the downstream side than the HTL nozzle 46(2). The GEL nozzle 46(4) is connected to the GEL evaporation source 30(4) via a gas line 48(4) that penetrates the bottom wall of the processing chamber 10 and is located at the fourth position in the sequence of the deposition scanning, i.e., at a position near the downstream side than the REL nozzle 46(3). The BEL nozzle 46(5) is connected to the REL evaporation source 30(5) via a gas line 48(5) that penetrates the bottom wall of the processing chamber 10 and is located at the fifth position in the sequence of the deposition scanning, i.e., at a position near the downstream side than the GEL nozzle 46(5).

The ETL nozzle 46(6) is connected to the ETL evaporation source 30(6) via a gas line 48(6) that penetrates the bottom wall of the processing chamber 10 and is located at the sixth position in the sequence of the deposition scanning, i.e., near the downstream side than the BEL nozzle 46(5). The EIL nozzle 46(7) is connected to the EIL evaporation source 30(7) via a gas line 48(7) that penetrates the bottom wall of the processing chamber 10 and is located at the last position in the sequence of the deposition scanning, i.e., at a position near the downstream side than the ETL nozzle 46(6).

Opening/closing valves 50(1) to 50(7) are provided at the gas lines 48(1) to 48(7), respectively. These opening/closing valves 50(1) to 50(7) are configured to be independently opened or closed (turned ON or OFF) under the control of the controller 18. Further, in order to suppress adhesion of deposition source materials within the gas lines 48(1) to 48(7), it may be desirable to heat the gas lines 48(1) to 48(7) from the vicinity thereof. Likewise, it may be also desirable to heat the carrier gas lines 40(1) to 40(7) from the vicinity thereof.

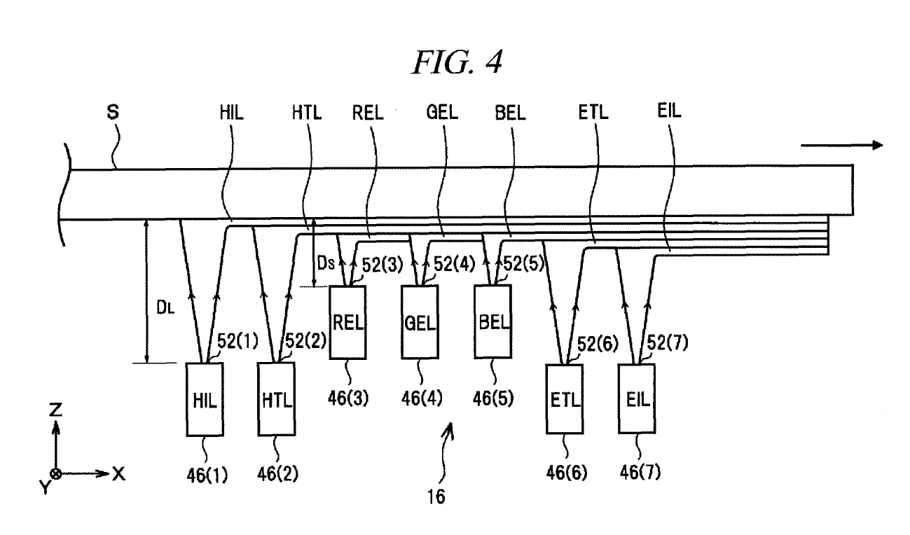

As depicted in FIG. 2, the nozzles 46(1) to 46(7) have discharge openings 52(1) to 52(7), respectively. To elaborate, the discharge openings 52(1), 52(2), 52(6) and 52(7), which are elongated in slit shapes along a nozzle lengthwise direction (Y direction), are formed on top surfaces of the HIL nozzle 46(1), the HTL nozzle 46(2), the ETL nozzle 46(6) and the EIL nozzle 46(7), respectively. The nozzles 46(1), 46(2), 46(6) and 46(7) are arranged such that the slit-shaped discharge openings 52(1), 52(2), 52(6) and 52(7) thereof are located at height positions (see FIG. 4) spaced apart from the substrate S, which is being moved directly above them during a deposition process. The height position of the slit-shaped discharge openings 52(1), 52(2), 52(6) and 52(7) is a relatively long distance D_{L} (typically, ranging from, e.g., about 10 mm to about 20 mm), which is suitable for forming plane-shaped thin films on the substrate S.

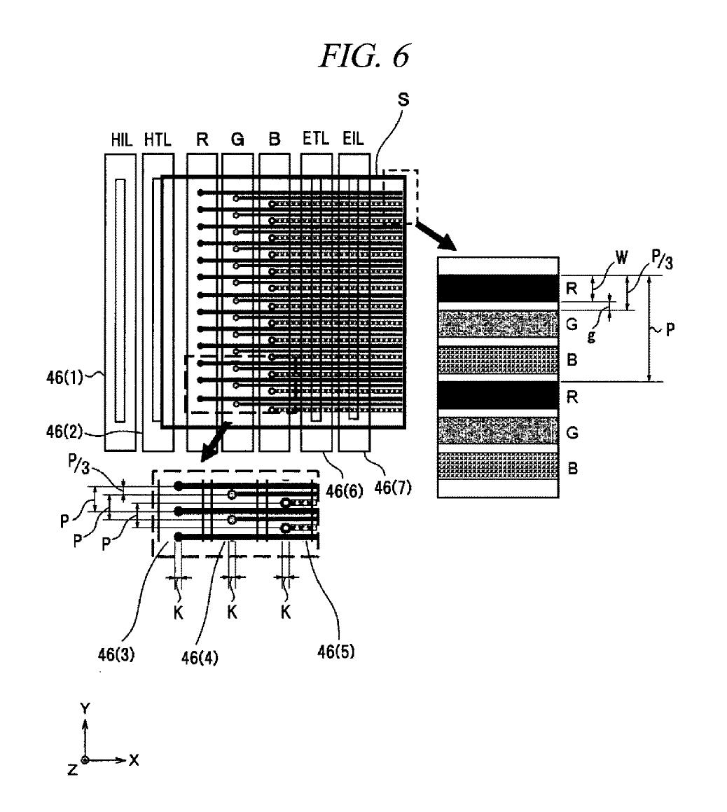

Meanwhile, the discharge openings 52(3), 52(4) and 52(5) are formed on top surfaces of the REL nozzle 46(3), the GEL nozzle 46(4) and the BEL nozzle 46(5) at height positions (see FIG. 4) spaced apart from the substrate S, which is being moved directly above them. The height position of the discharge openings 52(3), 52(4) and 52(5) is a relatively short distance D_{S} (typically, about 1 mm or less), which is suitable for forming a line-shaped thin films on the substrate S. The discharge openings 52(3), 52(4) and 52(5) are arranged in a single row (or plural rows) at a regular interval P in the nozzle lengthwise direction (Y direction). In the nozzles 46(3), 46(4) and 46(5), the discharge openings 52(3), 52(4) and 52(5) have the same diameter K, and they are offset from each other by about P/3 in the nozzle lengthwise direction (Y direction) (see FIG. 6).

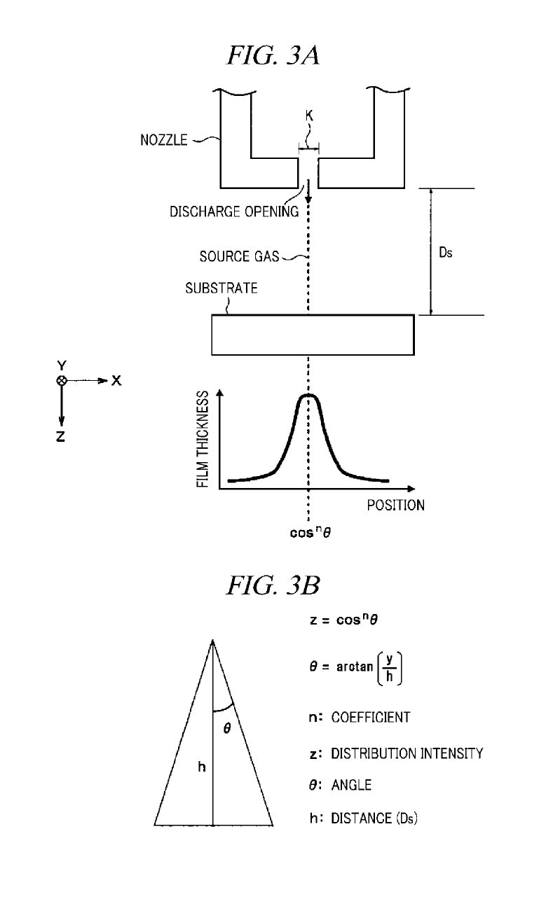

Here, the distance or pitch P between the discharge openings 52(3), 52(4) and 52(5) in the nozzle lengthwise direction (Y direction) is approximately identical with a pixel size in an organic EL display. Further, the diameter K of each of the discharge openings 52(3), 52(4) and 52(5) and the distance D_{S} are set based on a line width W of the juxtaposed R, G and B light emitting layers REL, GEL and BEL according to a cosine method as depicted in FIG. 3A and FIG. 3B. Desirably, the diameter K may be in the range from, e.g., about 0.1 W to about 1 W. By way of non-limiting example, when W equal to about 100 μm (W=100 μm), K may be set in the range from about 10 μm to about 100 μm (K=10 μm˜100 μm).

As stated above, the REL nozzle 46(3), the GEL nozzle 46(4) and the BEL nozzle 46(5) for forming the line-shaped thin films (R, G and B light emitting layers) is configured to discharge the source gases very thinly from the discharge openings 52(3), 52(4) and 52(5) thereof, respectively, toward a processing target surface of the substrate that is closely located at the distance D_{S}. Accordingly, the discharged source gases are not diffused all around, especially, in the substrate scanning direction (X direction). In contrast, the HIL nozzle 46(1), the HTL nozzle 46(2), the ETL nozzle 46(6) and the EIL nozzle 46(7) for forming the plane-shaped thin films HIL, HTL, ETL and EIL) is configured to discharge the source gases from the discharge openings 52(1), 52(2), 52(6) and 52(7) thereof, respectively, at a wide diffusion angle toward the processing target surface of the substrate that is located at the long distance D_{L} Accordingly, the discharge source gases are not diffused all around, especially, in the substrate scanning direction (X direction). For this reason, partition walls 52 vertically extending upward from the bottom wall of the processing chamber 10 to positions above the discharge openings are provided in front of and behind of (in FIG. 1, at the left and right sides) each of the nozzles 46(1), 46(2), 46(6) and 46(7), which discharge the sources gases at the wide diffusion angle and the long distance. These partition walls 52 suppress mixture or introduction of source gases between adjacent nozzles.

(Operation in Example Embodiment)

Now, referring to FIG. 4 to FIG. 6, an operation of the deposition apparatus in accordance with the present example embodiment will be discussed. After the gate valve 22 is opened, if a substrate S to be processed is loaded into the processing chamber 10 by an external transfer device (not shown), the controller 18 controls the moving device 12 to mount the substrate S on the stage 26 with its processing target surface facing downward. Here, when the loading of the substrate S is performed, the stage 26 is moved to the vicinity of the loading/unloading opening 24. Then, the stage 26 is moved to a scanning start position far from the loading/unloading opening 24. Upon the completion of the loading of the substrate S, the gate valve 22 is closed, and an inside of the processing chamber 10 is depressurized to a certain vacuum pressure by the gas exhaust device. Ai anode (ITO) has been formed on the processing target surface of the substrate S loaded into the processing chamber 10 in advance through a pre-process by another film forming apparatus (such as a sputtering apparatus).

The controller 18 controls the deposition device 14 to be in a stand-by state at the timing of loading the substrate S. By way of example, immediately before the substrate S is loaded, the heater power supply unit 34 may be turned ON, thus preparing for heating and evaporating film forming materials in the respective evaporation sources 30(1) to 30(7). Here, the opening/closing valves 50(1) to 50(7) are closed, and the source gas discharging unit 16 is stopped.

In order to perform a deposition process on the substrate S, the controller 18 controls the moving device 12 to start a scanning movement of the stage 26. In the scanning movement, if a front end of the substrate S reaches at the front of the HIL nozzle 46(1), the controller 18 controls the opening/closing valve 42(1) of the carrier gas supply line 40(1) and the opening/closing valve 50(1) of the source gas supply line 48(1) to be an open (ON) state from a closed (OFF) state, which is maintained until then, at a certain timing. Accordingly, the HIL nozzle 46(1) starts discharging a HIL source gas (exactly, a mixture gas of the HIL source gas and a carrier gas). The opening/closing valves 42(1) and 50(1) are maintained open (ON) until a rear end of the substrate S completely passes through above a head of the HIL nozzle 46(1), thus allowing the HIL nozzle 46(1) to continue discharging the HIL source gas. The mass flow controller (MFC) 44(1) controls a gas discharging pressure or a gas flow rate of the HIL nozzle 46(1) to a set value by controlling a pressure or a flow rate of the carrier gas flowing in the carrier gas supply line 40(1).

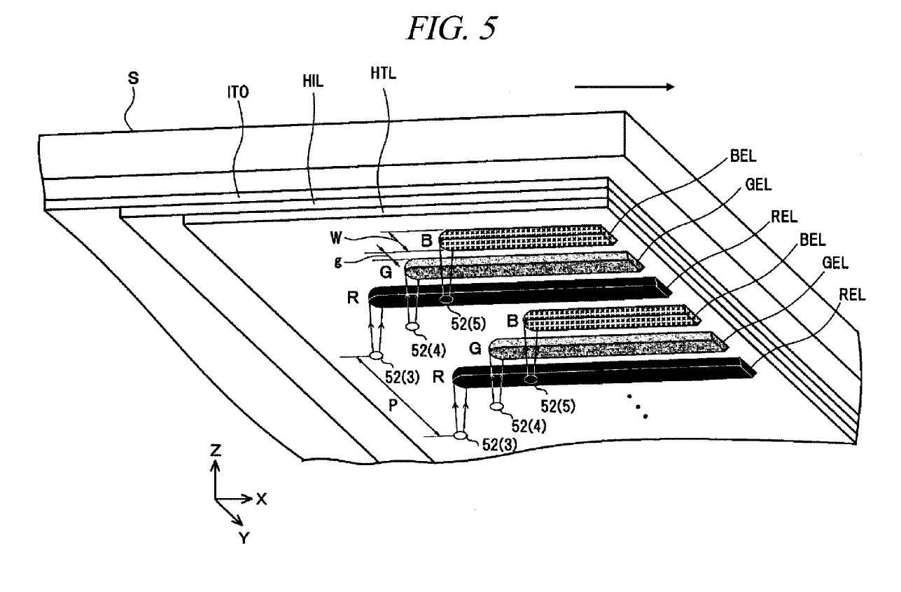

The HIL nozzle 46(1) discharges the HIL source gas in a stripe shape directly upward from the slit-shaped discharge opening 52(1) thereof. The HIL source gas discharged in the stripe shape may come into contact with the processing target surface of the substrate 5, which is being moved directly above the HIL nozzle 46(1), in the stripe shape and may be condensed and deposited at that contact position on the substrate S. In this way, as illustrated in FIG. 4 and FIG. 5, while the substrate S is being moved above the HIL nozzle 46(1) in the scanning direction (X direction) at a constant speed, a thin film of the hole injection layer (HIL) is deposited on the entire processing target surface of the substrate S in a plane shape having a certain thickness from the front end toward a rear end thereof.

Further, in the scanning movement, if the front end of the substrate S reaches at the front of the HTL nozzle 46(2), the controller 18 controls the opening/closing valve 42(2) of the carrier gas supply line 40(2) and the opening/closing valve 50(2) of the source gas supply line 48(2) to be an open (ON) state from a closed (OFF) state, which is maintained until then, at a certain timing. Accordingly, the HTL nozzle 46(2) starts discharging a HTL source gas (exactly, a mixture gas of the HTL source gas and the carrier gas). The opening/closing valves 42(2) and 50(2) are maintained open (ON) until the rear end of the substrate S completely passes through above a head of the HTL nozzle 46(2), thus allowing the HTL nozzle 46(2) to continue discharging the HTL source gas. The mass flow controller (MFC) 44(2) controls a gas discharging pressure or a gas flow rate of the HTL nozzle 46(2) to a set value by controlling a pressure or a flow rate of the carrier gas flowing in the carrier gas supply line 40(2).

The HTL nozzle 46(2) discharges the HTL source gas in a stripe shape directly upward from the slit-shaped discharge opening 52(2) thereof. The HTL source gas discharged in the stripe shape may come into contact with the processing target surface of the substrate S, which is being moved directly above the HTL nozzle 46(2), in the stripe shape and may be condensed and deposited at that contact position on the substrate S. In this way, as illustrated in FIG. 4 and FIG. 5, while the substrate S is being moved above the HTL nozzle 46(2) in the scanning direction (X direction) at a constant speed, a thin film of the hole transport layer (HTL) is deposited on the hole injection layer (HIL) in a plane shape having a certain thickness, following the hole injection layer (HIL) from the front end of the substrate S toward the rear end thereof.

Further, in the scanning movement, if the front end of the substrate S reaches at the front of the REL nozzle 46(3), the controller 18 controls the opening/closing valve 42(3) of the carrier gas supply line 40(3) and the opening/closing valve 50(3) of the source gas supply line 48(3) to be an open (ON) state from a closed (OFF) state, which is maintained until then, at a certain timing. Accordingly, the REL nozzle 46(3) starts discharging a REL source gas (exactly, a mixture gas of the REL source gas and the carrier gas). The opening/closing valves 42(3) and 50(3) are maintained open (ON) until the rear end of the substrate S completely passes through above a head of the REL nozzle 46(3), thus allowing the REL nozzle 46(3) to continue discharging the REL source gas. The mass flow controller (MFC) 44(3) controls a gas discharging pressure or a gas flow rate of the REL nozzle 46(3) to a set value by controlling a pressure or a flow rate of the carrier gas flowing in the carrier gas supply line 40(3).

The REL nozzle 46(3) discharges the REL source gas in a comb-teeth shape directly upward from the discharge openings 52(3) thereof. The REL source gas discharged in the comb-teeth shape may discretely come into contact with the processing target surface of the substrate S, which is being moved directly above the REL nozzle 46(3), and may be condensed and deposited at those discrete contact positions on the substrate S. In this way, as illustrated in FIG. 4, FIG. 5 and FIG. 6, while the substrate S is being moved above the REL nozzle 46(3) in the scanning direction (X direction) at a constant speed, a multiple number of thin films of R light emitting layer (REL) are deposited on the hole transport layer (HTL) in line shapes having a certain thickness and at a certain interval P, following the hole injection layer (HIL) and the hoe transport layer (HTL) from the front end of the substrate S toward the rear end thereof.

Likewise, in the scanning movement, if the front end of the substrate S reaches at the front of the GEL nozzle 46(4), the controller 18 controls the opening/closing valve 42(4) of the carrier gas supply line 40(4) and the opening/closing valve 50(4) of the source gas supply line 48(4) to be an open (ON) state from a closed (OFF) state, which is maintained until then, at a certain timing. Accordingly, the GEL nozzle 46(4) starts discharging a REL source gas (exactly, a mixture gas of the GEL source gas and the carrier gas). The opening/closing valves 42(4) and 50(4) are maintained open (ON) until the rear end of the substrate S completely passes through above a head of the GEL nozzle 46(4), thus allowing the GEL nozzle 46(4) to continue discharging the GEL source gas. The mass flow controller (MFC) 44(4) controls a gas discharging pressure or a gas flow rate of the GEL nozzle 46(4) to a set value by controlling a pressure or a flow rate of the carrier gas flowing in the carrier gas supply line 40(4).

The GEL nozzle 46(4) discharges the GEL source gas in a comb-teeth shape directly upward from the discharge openings 52(4). The GEL source gas discharged in the comb-teeth shape may discretely come into contact with the processing target surface of the substrate 5, which is being moved directly above the GEL nozzle 46(4), and may be condensed and deposited at those discrete contact positions on the substrate S. In this way, as illustrated in FIG. 4, FIG. 5 and FIG. 6, while the substrate S is being moved above the GEL nozzle 46(4) in the scanning direction (X direction) at a constant speed, a multiple number of thin films of G light emitting layer (GEL) are deposited on the hole transport layer (HTL) in line shapes having a certain thickness and at the certain interval P, following the hole injection layer (HIL), the hole transport layer (HTL) and the R light emitting layer (REL) from the front end of the substrate S toward the rear end thereof. Here, the thin films of G light emitting layer (GEL) are formed near the R light emitting layer (REL) at a certain gap g therefrom. The gap g between the line-shaped coating films may be set to be g=(P−3W)/3 (see FIG. 6).

Likewise, in the scanning movement, if the front end of the substrate S reaches at the front of the BEL nozzle 46(5), the controller 18 controls the opening/closing valve 42(5) of the carrier gas supply line 40(5) and the opening/closing valve 50(5) of the source gas supply line 48(5) to be an open (ON) state from a closed (OFF) state, which is maintained until then, at a certain timing. Accordingly, the BEL nozzle 46(5) starts discharging a BEL source gas (exactly, a mixture gas of the BEL source gas and the carrier gas). The opening/closing valves 42(5) and 50(5) are maintained open (ON) until the rear end of the substrate S completely passes through above a head of the GEL nozzle 46(5), thus allowing the BEL nozzle 46(5) to continue discharging the BEL source gas. The mass flow controller (MFC) 44(5) controls a gas discharging pressure or a gas flow rate of the BEL nozzle 46(5) to a set value by controlling a pressure or a flow rate of the carrier gas flowing in the carrier gas supply line 40(5).

The BEL nozzle 46(5) discharges the BEL source gas in a comb-teeth shape directly upward from the discharge openings 52(5). The BEL source gas discharged in the comb-teeth shape may discretely come into contact with the processing target surface of the substrate S, which is being moved directly above the BEL nozzle 46(5), and may be condensed and deposited at those discrete contact positions on the substrate S. In this way, as illustrated in FIG. 4, FIG. 5 and FIG. 6, while the substrate S is being moved above the BEL nozzle 46(5) in the scanning direction (X direction) at a constant speed, a multiple number of thin films of B light emitting layer (BEL) are deposited on the hole transport layer (HTL) in line shapes having a certain thickness and at the certain interval P, following the hole injection layer (HIL), the hole transport layer (HTL), the R light emitting layer (REL) and the G light emitting layer (GEL) from the front end of the substrate S toward the rear end thereof. Here, the thin films of B light emitting layer (BEL) are formed near the R light emitting layer (REL) and the G light emitting layer (GEL) at the gap g therefrom.

Then, in the scanning movement, if the front end of the substrate S reaches at the front of the ETL nozzle 46(6), the controller 18 controls the opening/closing valve 42(6) of the carrier gas supply line 40(6) and the opening/closing valve 50(6) of the source gas supply line 48(6) to be an open (ON) state from a closed (OFF) state, which is maintained until then, at a certain timing. Accordingly, the ETL nozzle 46(6) starts discharging an ETL source gas (exactly, a mixture gas of the ETL source gas and the carrier gas). The opening/closing valves 42(6) and 50(6) are maintained open (ON) until the rear end of the substrate S completely passes through above a head of the ETL nozzle 46(6), thus allowing the ETL nozzle 46(6) to continue discharging the ETL source gas. The mass flow controller (MFC) 44(6) controls a gas discharging pressure or a gas flow rate of the ETL nozzle 46(2) to a set value by controlling a pressure or a flow rate of the carrier gas flowing in the carrier gas supply line 40(6).

The ETL nozzle 46(6) discharges the ETL source gas in a stripe shape directly upward from the slit-shaped discharge opening 52(6) thereof. The ETL source gas discharged in the stripe shape may come into contact with the processing target surface of the substrate S, which is being moved directly above the HIL nozzle 46(6), in the stripe shape and may be condensed and deposited at that contact position on the substrate S. In this way, as illustrated in FIG. 4, while the substrate S is being moved above the ETL nozzle 46(6) in the scanning direction (X direction) at the constant speed, a thin film of the electron transport layer (ETL) is deposited on the hole transport layer (HTL) and the R, G and B light emitting layers (REL, GEL and BEL) in a plane shape having a certain thickness, following the hole injection layer (HIL), the hole transport layer (HTL), and the R, G and B light emitting layers (REL, GEL and BEL) from the front end of the substrate S toward a rear end thereof.

Finally, in the scanning movement, if the front end of the substrate S reaches at the front of the EIL nozzle 46(7), the controller 18 controls the opening/closing valve 42(7) of the carrier gas supply line 40(7) and the opening/closing valve 50(7) of the source gas supply line 48(7) to be an open (ON) state from a closed (OFF) state, which is maintained until then at a certain timing. Accordingly, the EIL nozzle 46(7) starts discharging an EIL source gas (exactly, a mixture gas of the EIL source gas and the carrier gas. The opening/closing valves 42(7) and 50(7) are maintained open (ON) until the rear end of the substrate S completely passes through above a head of the EIL nozzle 46(7), thus allowing the EIL nozzle 46(7) to continue discharging the EIL source gas. The mass flow controller (MFC) 44(7) controls a gas discharging pressure or a gas flow rate of the EIL nozzle 46(7) to a set value by controlling a pressure or a flow rate of the carrier gas flowing in the carrier gas supply line 40(7).

The EIL nozzle 46(7) discharges the REL source gas in a stripe shape directly upward from the slit-shaped discharge opening 52(7) thereof. The EIL source gas discharged in the stripe shape may come into contact with the processing target surface of the substrate S, which is being moved directly above the EIL nozzle 46(7), in the stripe shape and may be condensed and deposited at that contact position on the substrate S. In this way, as illustrated in FIG. 4, while the substrate S is being moved above the EIL nozzle 46(7) in the scanning direction (X direction) at the constant speed, a thin film of the electron injection layer (EIL) is deposited on the electron transport layer (ETL) in a plane shape having a certain thickness, following the hole injection layer (HIL), the hole transport layer (HTL), the R, G and B light emitting layers (REL, GEL and BEL) and the electron transport layer (ETL) from the front end of the substrate S toward a rear end thereof.

After the rear end of the substrate S passes through above the head of the EIL nozzle 46(7), the controller 18 controls the moving device 12 to stop the stage 28. Further, by controlling the deposition device 14 and the source gas discharging unit 16, the controller 18 changes the open state (ON state) of the opening/closing valve 42(7) of the carrier gas supply line 40(7) and the opening/closing valve 50(7) of the source gas supply line 48(7) to a closed (OFF) state. Subsequently, by controlling a purging device (not shown), the controller 18 controls the atmosphere within the processing chamber 10 to be an atmospheric pressure state from a depressurized state. Thereafter, the gate valve 22 is opened, and the processed substrate S is taken out of the processing chamber 10 by the external transfer device. Then, the processed substrate S is moved to another film forming apparatus (for example, a sputtering apparatus) so that the cathode is formed on the electron injection layer (EIL).

As described above, in the deposition apparatus in accordance with this example embodiment, just by moving the substrate S in one horizontal direction (X direction) only one time within the processing chamber 10, the multiple kinds of organic thin films, i.e., the hole injection layer (HIL), the hole transport layer (HIL), R, G and B light emitting layers (REL, GEL and BEL), the electron transport layer (ETL) and the electron injection layer (EIL) can be formed by vapor deposition. Among these layers, the R, G and B light emitting layers (REL GEL and BEL) can be formed in parallel line shapes to be arranged side by side. Accordingly, it may be possible to manufacture an organic EL color display having a device structure as illustrated in FIG. 7 through only one time of deposition process in the single processing chamber 10, without using a shadow mask at all. Therefore, the problems of the prior art regarding the shadow mask can be all solved. Further, an efficiency of using the organic materials, an efficiency of the selective deposition, an efficiency of formation of multiple layers, a production yield, a space efficiency and a cost efficiency can be greatly improved while facilitating scale-up of a screen or mass production effectively.

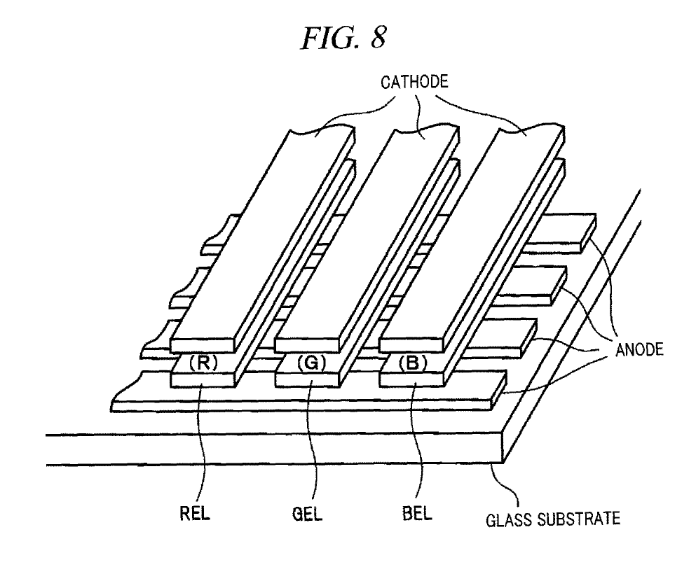

In addition, as a driving method for the organic EL color display having the device structure as depicted in FIG. 7, a passive matrix method as illustrated in FIG. 8 may be used, for example. In this case, an anode and a cathode may be formed as line-shaped electrodes (row electrode and column electrode) orthogonal to each other. If a voltage is applied to a pixel (an R: G or B sub pixel) at an intersection position where the two electrodes cross each other, the sub pixel emits light.

Alternatively, an active matrix may also be employed. In case of the active matrix, though not shown, a TFT (Thin Film Transistor), a pixel electrode, a scanning line and a signal line for each of R, G and B sub pixels are formed on a side of an anode (ITO). Meanwhile, a cathode is a common electrode, and the cathode may be implemented by a single sheet of plane-shaped thin film.

### Other Example Embodiments or Modification Examples

It should be noted that the above example embodiment has been described for the purpose of illustration, and that various modifications may be made without departing from the scope and spirit of the present disclosure.

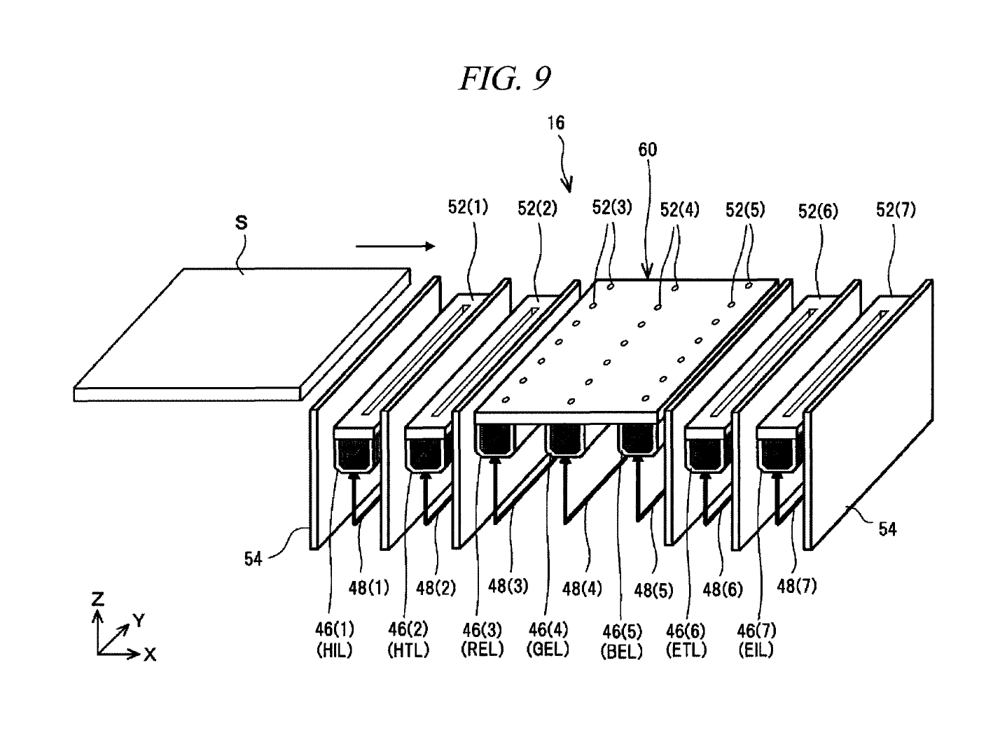

By way of non-limiting modification example, a configuration as Illustrated in FIG. 9 may be employed. In this configuration, the discharge openings 52(3), 52(4) and 52(5) of the REL nozzle 46(3), the GEL nozzle 46(4) and the BEL nozzle 46(5) configured to form the juxtaposed R, G and B light emitting layers (REL, GEL and BEL) in a source gas discharging unit 16 may be formed on a single plate body or a single discharge opening plate 60 commonly fastened to the nozzles 46(3), 46(4) and 46(5).

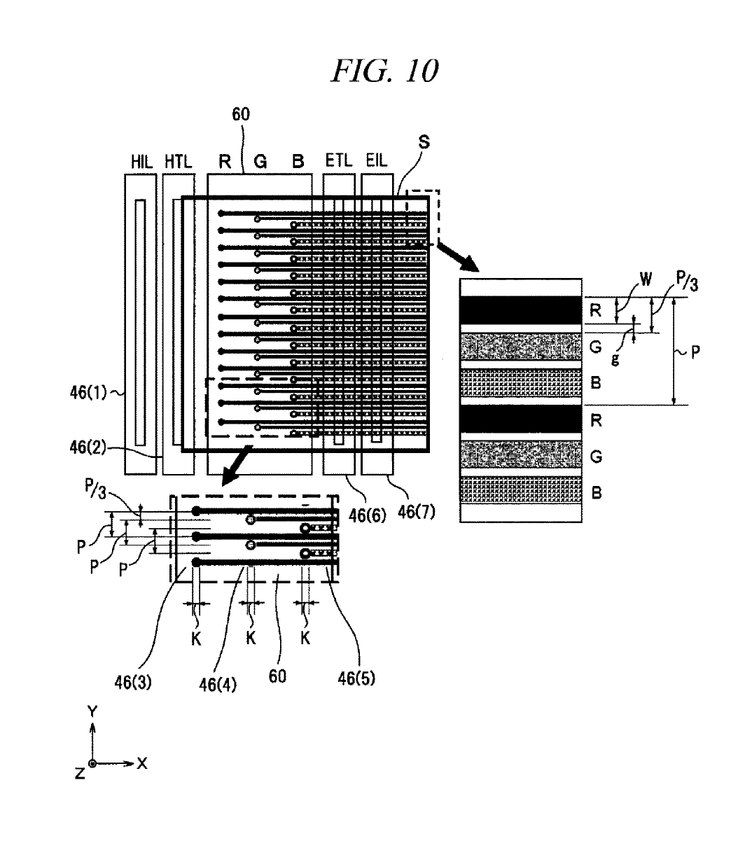

With this configuration, as illustrated in FIG. 10, between the nozzles 46(3), 46(4) and 46(5), a positional error or an offset amount of the discharge openings 52(3), 52(4) and 52(5) in a nuzzle lengthwise direction (Y direction) can be accurately adjusted to a set value (P/3). Thus, a troublesome alignment process can be omitted.

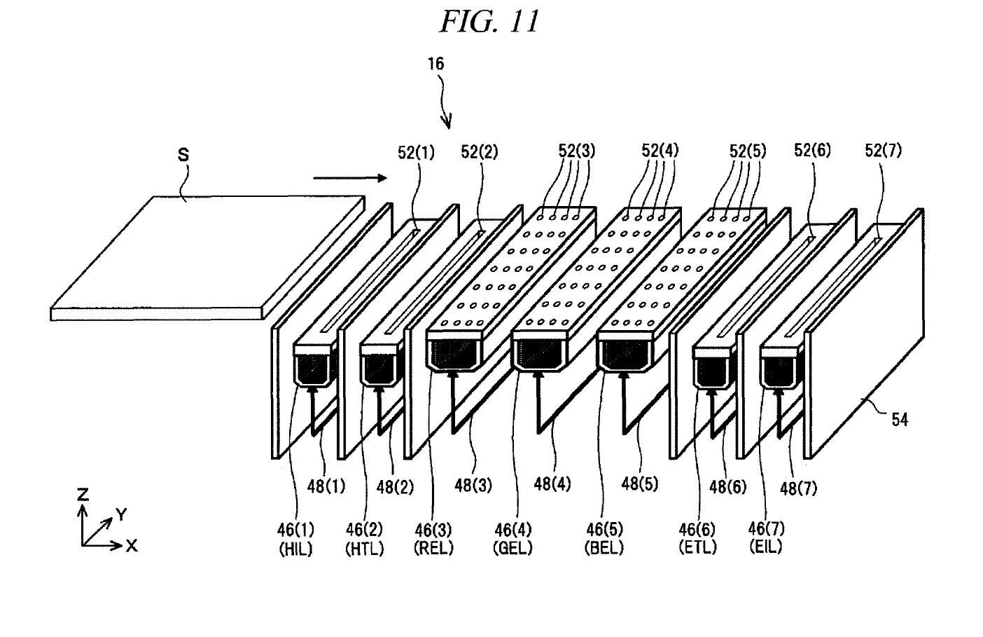

Further, as another modification example regarding the discharge openings 52(3), 52(4) and 52(5) of the REL nozzle 46(3), the GEL nozzle 46(4) and the BEL nozzle 46(5), it may be possible to employ a configuration as depicted in FIG. 11. In this configuration, in each nozzle 46(3), 46(4), and 46(5), the discharge openings 52(3), 52(4), and 52(5) are arranged in a single row, and a multiple number of this row (in the shown example, four rows) are formed in the scanning direction (X direction).

With this configuration, it may become possible to obtain a line-shaped thin film (REL, GEL, BEL) having a thickness several times larger than a thickness of a line-shaped thin film (REL, GEL, BEL) formed through a single opening 52(3), 52(4) and 52(5). In other aspect, it may be possible to reduce a pressure or a flow rate of a source gas several times less than a pressure or a flow rate of a source gas discharged from the single discharge opening 52(3), 52(4) and 52(5).

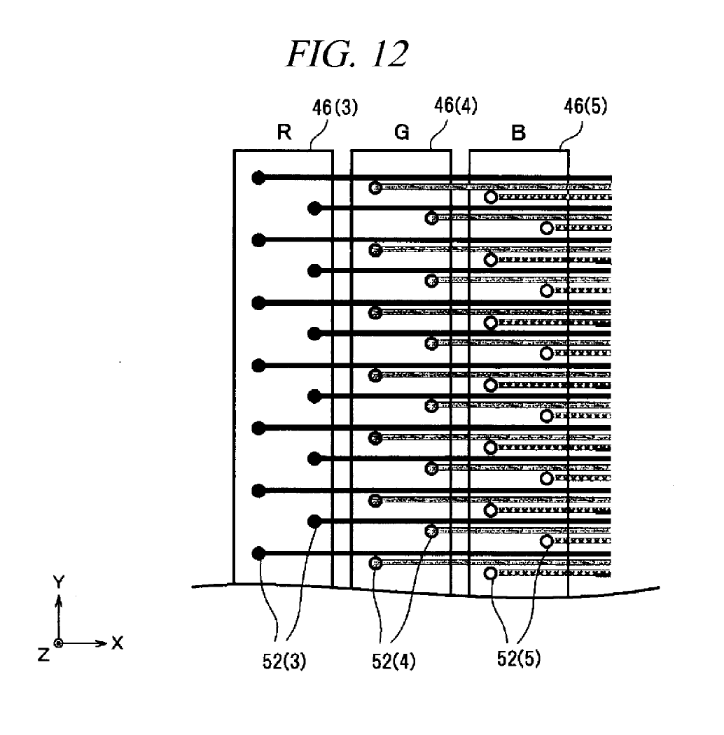

Furthermore, as still another modification example, it may be possible to employ a configuration in FIG. 12. In this configuration, the discharge openings 52(3), 52(4), and 52(5) of each nozzle 46(3). 46(4), and 46(5) are arranged in zigzag shape. With this configuration, an arrangement interval between the discharge openings 52(3), 52(4), and 52(5) in a nozzle lengthwise direction (Y direction) can be enlarged two times.

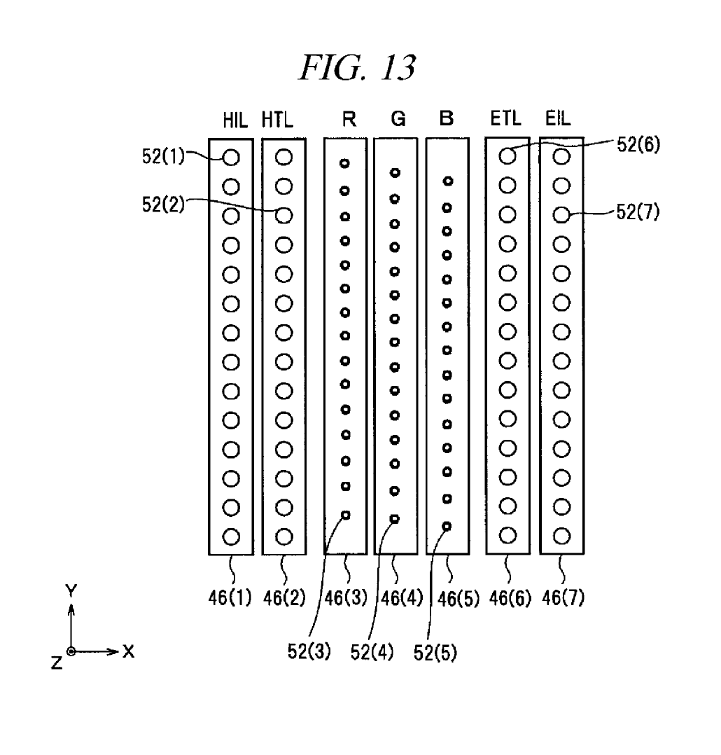

Further, as still another modification example, as illustrated in FIG. 13, each of the HIL nozzle 46(1), the HTL nozzle 46(2), the ETL nozzle 46(6) and the EIL nozzle 46(7) for forming the plane-shaped this films may have multiple discharge openings 52(3), 52(4), 52(6) and 52(7) arranged in a single row or multiple rows. In this case, the diameters and pitches of the discharge openings 52(3), 52(4), 52(6) and 52(7) and the distances (D_{L}) therebetween may be selected such that they could discharge the HIL source gas, the HTL source gas, the ETL source gas and the EIL source gas substantially in stripe shapes toward the substrate S that is being moved above them.

Further, in the deposition apparatus in accordance with the present example embodiment, the arrangement direction of each of the elongated nozzles for discharging the source materials, i.e., the lengthwise direction of each nozzle, is typically orthogonal (Y direction) to the substrate moving direction (X direction) as in the above-described embodiment. However, as required, the lengthwise direction of the nozzle may be set to be inclined with respect to the Y direction on a horizontal plane. Further, the posture of a substrate subjected to the deposition process may not be limited to the face-down posture and, by way of non-limiting example, a face-up posture or a posture with a processing target surface of the substrate facing to a transversal direction may also be possible. In each nozzle, the direction of discharging the source gas may be appropriately set according to the direction or the posture of a processing target substrate.

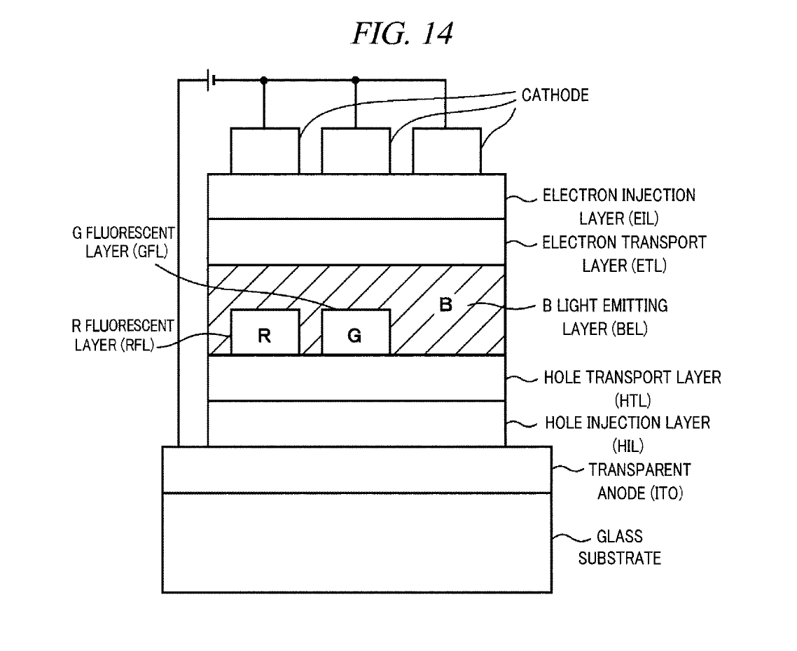

Further, as an organic EL display color light emitting method, there is also known a modified juxtaposed arrangement where a B light emitting layer (BEL), an R fluorescent layer (RFL) and a G fluorescent layer (GFL) are combined, as shown in FIG. 14. In this case, the R fluorescent layer (RFL) and the G fluorescent layer (GFL) made of organic materials are formed on a hole transport layer (HTL) as line-shaped thin films adjacent to each other, like the R light emitting layer (REL) and the G light emitting layer (GEL) as stated above. The B light emitting layer (BEL) is formed as a plane-shaped thin film that covers even the R fluorescent layer (RFL) and the G fluorescent layer (GFL), and also, fills B sub pixel positions.

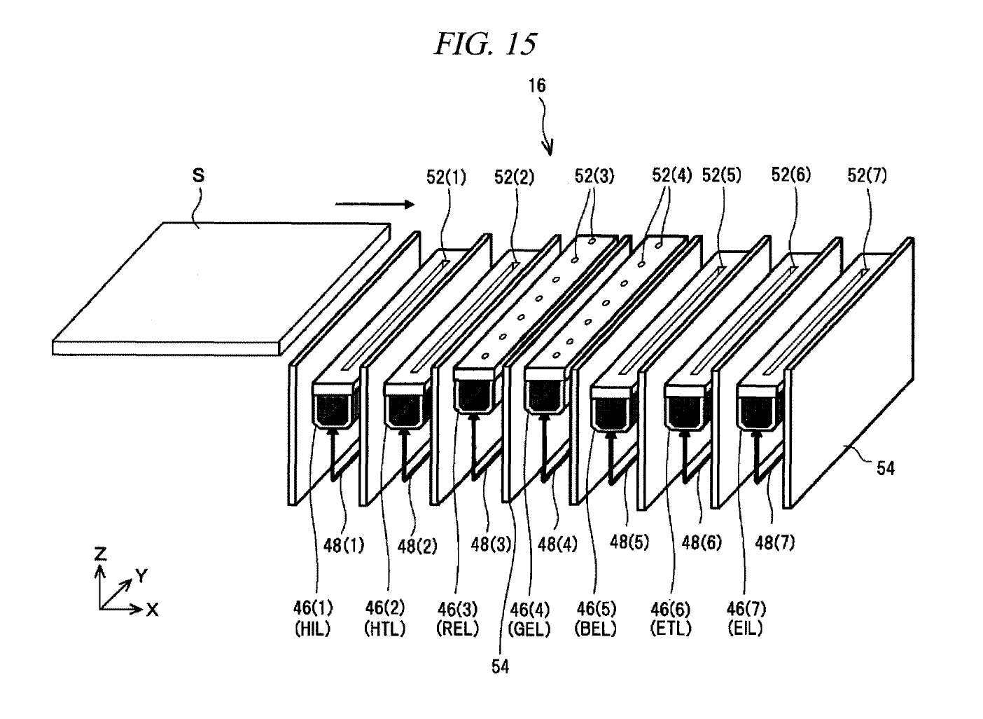

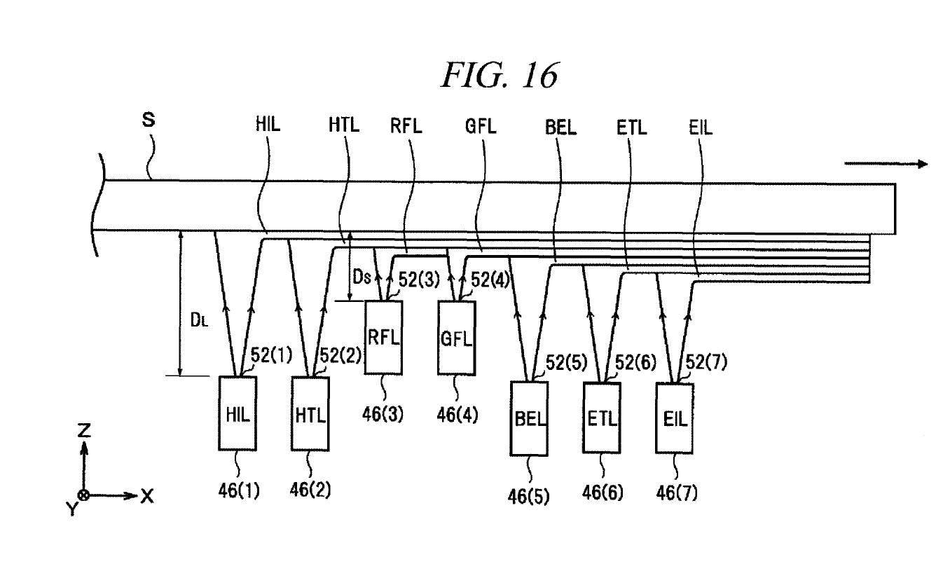

In case of manufacturing this device structure by using the example embodiment, a discharge opening 52(5) of a BEL nozzle 46(5) may be formed to have a slit shape (or a multi-hole shape capable of discharging a gas substantially in a stripe shape) and may be provided at a height position spaced apart from a substrate S, which is being moved directly above the discharge opening 52(5). The height position thereof is a relatively large distance D_{L} (typically, ranging from, e.g., about 10 mm to about 20 mm), which is suitable for forming a plane-shaped thin film on the substrate S, as depicted in FIG. 15 and FIG. 16.

In a deposition process, film forming operations of other nozzles 46(1) to 46(4), 46(6) and 46(7) are substantially the same as those described in the aforementioned example embodiment. Only the film forming operation of the BEL nozzle 46(5) is greatly different from that of the aforementioned example embodiment. That is, the BEL nozzle 46(3) discharges a BEL source gas in a stripe shape directly upward from the slit-shaped (or multi-hole) discharge opening 52(5). The BEL source gas discharged in the stripe shape may come into contact with a processing target surface of the substrate S, which is being moved directly above it, in the stripe shape and may be condensed and deposited at that stripe-shaped contact position. In this way, as illustrated in FIG. 16, while the substrate S is being moved above the BEL nozzle 46(5) in a scanning direction (X direction) at a regular speed, a thin film of a G light emitting layer (GEL) is deposited around and on top of the R fluorescent layer (RFL) and the G fluorescent layer (GFL) in a plane shape having a certain thickness, following the hole injection layer (HIL), the hole transport layer (HTL), the R fluorescent layer (RFL) and the G fluorescent layer (GFL) from a front end of the substrate S toward a rear end thereof.

Further, in this example, the R fluorescent layer (RFL) and the G fluorescent layer (GFL), which are organic materials, may be substituted with an R phosphor layer (RPL) and a G phosphor layer (GPL), which are organic materials, respectively.

In a source gas discharging unit 16 shown in FIG. 15, a partition wall 52 is provided between the REL nozzle 46(3) and the GEL nozzle 46(4). By providing the partition wall 52 between the adjacent nozzles for forming line-shaped thin films, recoil (rebound) of organic molecules (molecules of the source gases) can be more effectively suppressed. In the above-described example source gas discharging unit 16 (see, for example, FIG. 1), partition walls 52 may also be provided between the REL nozzle 46(3) and the GEL nozzle 46(4) and between the GEL nozzle 46(4) and the BEL nozzle 46(5) for the same purpose.

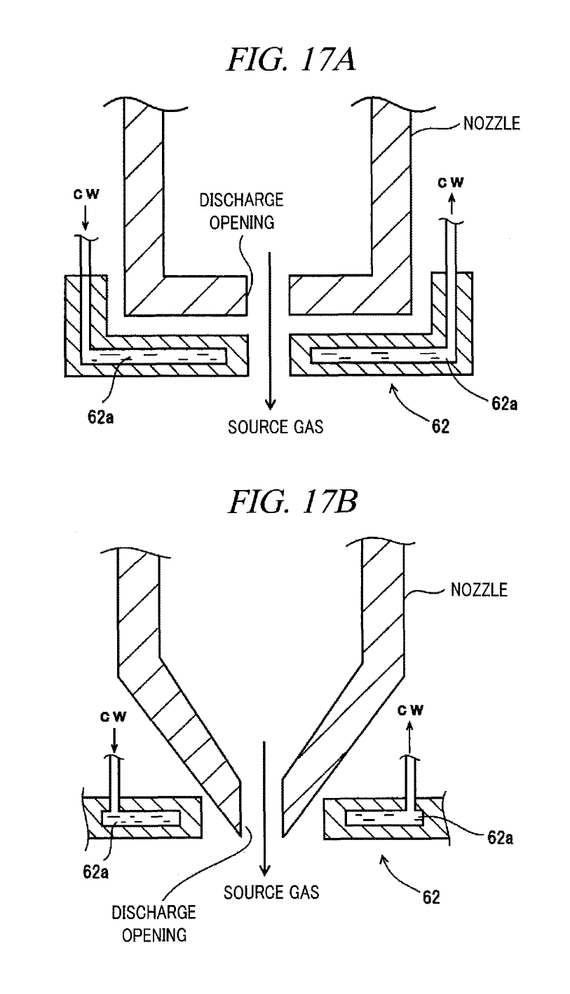

Further, in the deposition apparatus of the example embodiment, since a discharge opening of a nozzle for forming a line-shaped thin film is located at a close position to a processing target surface of a substrate, it may be appropriately provided a member configured to suppress an influence of radiant heat from the nozzle upon an organic film on the substrate. By way of non-limiting example, as depicted in FIG. 17A, a plate-shaped heat insulating unit 62 may be provided in the vicinity of a discharge opening of a nozzle. This heat insulating unit 62 may be formed of a material having high thermal conductivity and have therein a flow path 62a through which a cooling medium cw (for example, cooling water) is flown. Thus, the heat insulating unit 62 can absorb and block the heat radiated from the nozzle.

Further, as depicted in FIG. 17B, since a leading end of a nozzle may be formed in a shape that tapers toward a discharge opening, the heat insulating unit 62 may be located at a side position of the discharge opening of the nozzle, not in front of the discharge opening of the nozzle. With this configuration, the discharge opening of the nozzle can be placed as close to a substrate (not shown) as possible.

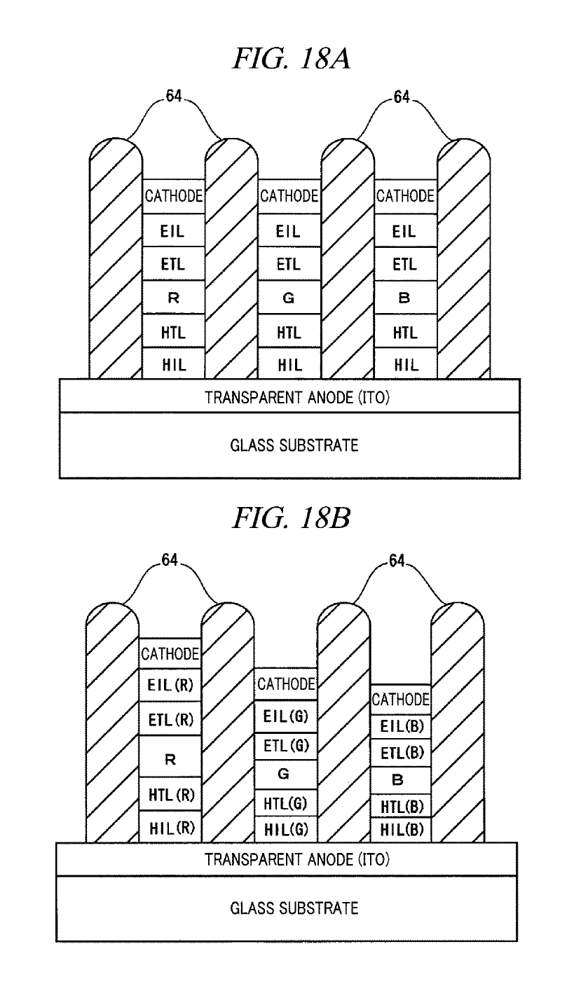

The deposition apparatus in accordance with the example embodiment may also be advantageously applied to manufacturing a device structure where a partition wall or a bank for the separation of sub pixels between various colors of light emitting layers on a substrate. According to this sub pixel separation method, as illustrated in FIG. 18A, not only the R, G and B light emitting layers (REL, GEL, BEL) but also the hole injection layer (HIL), the hole transport layer (HTL), the electron transport layer (ETL) and the electron injection layer (EIL) are separated by partition walls (banks) 64 for the respective colors. In this case, while setting thicknesses of organic thin films in the respective layers (a first layer (HIL), a second layer (HTL), . . . ) to be uniform, film qualities or materials of respective layers may be individually selected to optimize light emitting characteristics of the respective colors independently. Further, as illustrated in FIG. 18B, it may be also possible to control the thicknesses of the respective thin films independently for each color depending on the light emitting characteristics of each color. By way of example, but not limitation, the film thickness of the R light emitting layer (REL), the G light emitting layer (GEL) and the B light emitting layer (BEL) may be set to be in the range of about 140±20 nm, 120±20 nm, 100±20 nm, respectively.

When forming a line-shaped organic thin film in the deposition apparatus in accordance with the example embodiment, a shadow mask is not necessary, as mentioned above. However, when forming a topmost cathode in a line shape through a post-process such as a sputtering process, a shadow mask may be used. In such a case, the banks 64, which are formed higher than the organic thin films for the various colors, may suppress the organic thin films from being brought into contact with the shadow mask.

The banks 64 may be made of an organic material such as, but not limited to, an acryl resin, a novolak resin, a polyamide resin or a polyimide resin. The banks 64 may be formed through a pre-process by, for example, an inkjet method or a printing method. Further, the banks 64 may be formed on a substrate S along with light emitting layers or the like in the deposition apparatus by the deposition method in accordance with the example embodiment.

When manufacturing the above-described device structure in the deposition apparatus in accordance with the example embodiment, an evaporation source, a nozzle carrier gas supply unit (an exclusive gas line, an opening/closing valve, a MFC, etc.) and so forth, which are required to form the banks 64, are additionally provided in the evaporating device 14, the source gas discharging unit 16 and the carrier gas supply device 36. It is desirable to locate a nozzle for forming the banks at a position upstream of the HIL nozzle 46(1), i.e., at the most upstream position. Further, all the nozzles including the nozzle for forming the banks, the nozzles 46(3), 46(4) and 46(5) for forming the light emitting layers, the nozzles 46(1) and 46(7) for forming injection layers and the nozzles 46(2) and 46(6) for forming the transport layers have multiple discharge openings having small diameters and are located at height positions where the nozzles can discharge source gases to the substrate S at the short distance D_{S}. The thickness of each line-shaped thin film or the line-shaped bank may be individually controlled or adjusted depending on a flow rate of each source gas, a diameter of a nozzle discharge opening, the number of discharge openings (in the case of FIG. 10), and so forth.

As in this example, one or all of the HIL nozzle 46(1), the HTL nozzle 46(2), the ETL nozzle 46(6) and the EIL nozzle 46(7) may be provided in plural for each color.

In the above-described embodiment and examples, while performing the deposition scanning, the line-shaped various colors of light emitting layers are formed on the substrate S in the order of the R light emitting layer (REL), the G light emitting layer (GEL) and the B light emitting layer (BEL). However, the order for deposition may not be limited thereto, the line-shaped various colors of light emitting layers may be formed in any order. Accordingly, in the source gas discharging unit 16, the arrangement order of the REL nozzle 46(3), the GEL nozzle 46(4) and the BEL nozzle 46(5) may be selected as required.

Further, in the above-described embodiment and examples, the respective organic layers are deposited in the sequence order of the hole injection layer (HIL), the hole transport layer (HTL), or the like, on the transparent anode (ITO) serving as a base layer. However, it may be also possible to deposit the respective organic layers in the reverse order, i.e., in the order of the electron injection layer (HIL), the electron transport layer (ETL) or the like, while using the cathode as a base layer.

Further, some organic EL displays may have a device structure where a part of the hole injection layer (HIL), the hole transport layer (HTL), the electron transport layer (ETL) and the electron injection layer (EIL) is omitted. The present disclosure may be also applicable to the manufacture of such a device structure.

Further, in the above-described example embodiment, all the multiple layers forming the organic EL display is made of organic materials. However, the present disclosure is also applicable to the manufacture of a device structure in which a part or all of the organic thin films are substituted with an inorganic material thin film. Further, the present disclosure is also applicable to an organic EL having a multi-photon light emitting structure.

Although the above example embodiment has been described for an organic EL display, the present disclosure can be applied to any film forming processes or applications for depositing a multiple number of line-shaped thin films on a substrate selectively by using a vapor deposition method. Accordingly, by way of example, a line width W of each line-shaped thin film, a diameter of a discharge opening of each nozzle, and a distance D may be independently set for each kind of line-shaped thin film.

By using the deposition apparatus and the deposition method in accordance with the present example embodiment, a lighting device can be manufactured. That is, by using the deposition apparatus and the deposition method, an R light emitting layer, a G light emitting layer and a B light emitting layer can be formed in line shapes on a substrate, and by allowing the respective light emitting layers to emit light, a lighting device that emits white light can be manufactured. Further, by way of example, by using the deposition apparatus and the deposition method, an R light emitting layer, a G light emitting layer and a B light emitting layer can be formed in line shapes on a substrate, and by allowing the light emission intensity of each light emitting layer to be adjustable, a lighting device capable of the color of emitted light can be manufactured.

### EXPLANATION OF CODES

10: Processing chamber
12: Moving device
14: Deposition device
16: Source gas discharging unit
18: Controller
20: Gas exhaust opening
26: Stage
28: Scanning unit
30(1) to 30(7): Evaporation source
34: Heater power supply unit
38: Carrier gas supply source
44(1) to 44(7): Mass flow controller (MFC)
46(1) to 46(7): Nozzle
48(1) to 48(7): Gas line
50(1) to 50(7): Opening/closing valve
60: Discharge opening plate
62: Heat insulating unit
64: Bank (partition wall)

1-26. (canceled)

27. A deposition method, comprising:
moving a substrate in a first direction within a processing chamber;
generating a first source gas by evaporating a first film forming source material;
discharging the first source gas from at least one first discharge opening toward the substrate being moved in the processing chamber;
forming a first line-shaped thin film elongated in the first direction by depositing the first source gas on the substrate;
generating a second source gas by evaporating a second film forming source material;
discharging the second source gas from at least one second discharge opening offset from the at least one first discharge opening in a second direction, which intersects the first direction, toward the substrate being moved in the processing chamber; and
forming a second line-shaped thin film elongated in the first direction by depositing the second source gas on the substrate at a position spaced apart from the first line-shaped thin film.

28. The deposition method of claim 27,
wherein the at least one first discharge opening is plural in number, and the first discharge openings are arranged at a regular interval therebetween in the second direction,
the at least one second discharge opening is plural in number, and the second discharge openings are arranged at a regular interval therebetween in the second direction, and
the first line-shaped thin film and the second line-shaped thin film are repeatedly and alternately formed on the substrate in the second direction.

29. A deposition method, comprising:
moving a substrate in a first direction within a processing chamber;
generating a first source gas by evaporating a first film forming source material;
discharging the first source gas from at least one first discharge opening toward the substrate being moved in the processing chamber;
forming a first line-shaped thin film elongated in the first direction by depositing the first source gas on the substrate;
generating a second source gas by evaporating a second film forming source material;
discharging the second source gas from the at least one second discharge opening offset from the at least one first discharge opening in a second direction, which intersects the first direction, toward the substrate being moved in the processing chamber;
forming a second line-shaped thin film elongated in the first direction by depositing the second source gas on the substrate at a position spaced apart from the first line-shaped thin film;
generating a third source gas by generating a third film forming source material;
discharging the third source gas from at least one third discharge opening offset from the at least one first discharge opening and the at least one second discharge opening in the second direction, which intersects the first direction, toward the substrate being moved in the processing chamber; and
forming a third line-shaped thin film elongated in the first direction by depositing the third source gas on the substrate at a position spaced apart from the first line-shaped thin film and the second line-shaped thin film.

30. The deposition method of claim 29,
wherein the at least one first discharge opening is plural in number, and the first discharge openings are arranged at a regular interval therebetween in the second direction,
the at least one second discharge opening is plural in number, and the second discharge openings are arranged at a regular interval therebetween in the second direction,
the at least one third discharge opening is plural in number, and the third discharge openings are arranged at a regular interval therebetween in the second direction, and
the first line-shaped thin film, the second line-shaped thin film and the third line-shaped thin films are repeatedly and alternately formed on the substrate in the second direction.

31. The deposition method of claim 29,
wherein the at least one third discharge opening is plural in number, and the third discharge openings are arranged in a single row in the second direction, and
the third line-shaped thin film is formed on the substrate by multiple-layer vapor deposition.

32. The deposition method of claim 29,
wherein if a set value of a line width of the third line-shaped thin film is W3, a diameter K3 of the at least one third discharge opening is set to be in the range from about 0.1 W3 to about 1.0 W3.

33. The deposition method of claim 29,
wherein the third line-shaped thin film is a light emitting layer.

34. A deposition method, comprising:
moving a substrate in a first direction within a processing chamber;
generating a first source gas by evaporating a first film forming source material;
discharging the first source gas from a first discharge opening toward the substrate being moved in the processing chamber;
forming a first line-shaped thin film elongated in the first direction by depositing the first source gas on the substrate;
generating a second source gas by evaporating a second film forming source material;
discharging the second source gas from a second discharge opening offset from the first discharge opening in a second direction, which intersects the first direction, toward the substrate being moved in the processing chamber;
forming a second line-shaped thin film elongated in the first direction by depositing the second source gas on the substrate at a position spaced apart from the first line-shaped thin film;
generating a third source gas by generating a third film forming source material;
discharging the third source gas, toward the substrate being moved in the processing chamber, from a third discharge opening offset from the first discharge opening and the second discharge opening in the first direction toward a downstream side of a substrate moving direction; and
forming a first plane-shaped thin film by depositing the third source gas on the first line-shaped thin film and the second line-shaped thin film on the substrate.

35. The deposition method of claim 34,
wherein the first line-shaped thin film and the second line-shaped thin film are fluorescent layers or phosphorous layers, and the first plane-shaped thin film is a light emitting layer.

36. The deposition method of claim 34, further comprising:
generating a fourth source gas by evaporating a fourth film forming source material;
discharging the fourth source gas toward the substrate being moved in the processing chamber from a fourth discharge opening offset from the third discharge opening in the first direction toward a downstream side of the substrate moving direction; and
forming a second plane-shaped thin film by depositing the fourth source gas on the first plane-shaped thin film on the substrate.

37. A deposition method, comprising:
moving a substrate in a first direction within a processing chamber;
generating a first source gas by evaporating a first film forming source material;
discharging the first source gas from a first discharge opening toward the substrate being moved in the processing chamber;
forming a first line-shaped thin film elongated in the first direction by depositing the first source gas on the substrate;
generating a second source gas by evaporating a second film forming source material;
discharging the second source gas from a second discharge opening offset from the first discharge opening in a second direction, which intersects the first direction, toward the substrate being moved in the processing chamber;
forming a second line-shaped thin film elongated in the first direction by depositing the second source gas on the substrate at a position spaced apart from the first line-shaped thin film;
generating a third source gas by generating a third film forming source material;
discharging the third source gas, toward the substrate being moved in the processing chamber, from a third discharge opening offset from the first discharge opening and the second discharge opening in the first direction toward an upstream side of a substrate moving direction; and
forming a first plane-shaped thin film by depositing the third source gas on the substrate before the first line-shaped thin film and the second line-shaped thin film are formed.

38. The deposition method of claim 37, further comprising:
generating a fourth source gas by evaporating a fourth film forming source material;
discharging the fourth source gas, toward the substrate being moved in the processing chamber, from a fourth discharge opening offset from the third discharge opening in the first direction toward an upstream side of the substrate moving direction; and
forming a second plane-shaped thin film by depositing the fourth source gas on the substrate before the first plane-shaped thin film is formed.

39. The deposition method of claim 36,
wherein the fourth discharge opening is located at a position further from the substrate than the first discharge opening and second discharge opening.

40. The deposition method of claim 36,
wherein the fourth source gas is discharged from the fourth discharge opening at a predetermined pressure or flow rate while being mixed with a carrier gas.

41. The deposition method of claim 36,
wherein the fourth film forming source material is an organic material.

42. The deposition method of claim 34,
wherein the third discharge opening is located at a position further from the substrate than the first discharge opening and second discharge opening.

43. A deposition method, comprising:
moving a substrate in a first direction within a processing chamber;
generating a first source gas by evaporating a first film forming source material;
discharging the first source gas from a first discharge opening toward the substrate being moved in the processing chamber;
forming a first line-shaped thin film elongated in the first direction by depositing the first source gas on the substrate;
generating a second source gas by evaporating a second film forming source material;
discharging the second source gas from a second discharge opening offset from the first discharge opening in a second direction, which intersects the first direction, toward the substrate being moved in the processing chamber;
forming a second line-shaped thin film elongated in the first direction by depositing the second source gas on the substrate at a position spaced apart from the first line-shaped thin film;
generating a third source gas by generating a third film forming source material;
discharging the third source gas from a third discharge opening offset from the first discharge opening and second discharge opening in the second direction, which intersects the first direction, toward the substrate being moved in the processing chamber; and
forming a partition wall elongated in the first direction by depositing the third source gas on the substrate to fill a space between a region where the first line-shaped thin film is formed and a region where the second line-shaped thin film are formed.

44. The deposition method of claim 29,
wherein the third source gas is discharged from the at least one third discharge opening at a predetermined pressure or flow rate while being mixed with a carrier gas.

45. The deposition method of claim 29,
wherein the third film forming source material is an organic material.

46. The deposition method of claim 27,
wherein the at least one first discharge opening is plural in number, and the first discharge openings are arranged in a single row in the second direction, and
the first line-shaped thin film is formed on the substrate by multiple-layer vapor deposition.

47. The deposition method of claim 27,
wherein the at least one second discharge opening is plural in number, and
the second discharge openings are arranged in a single row in the second direction, and
the second line-shaped thin film is formed on the substrate by multiple-layer vapor deposition.

48. The deposition method of claim 27,
wherein if a set value of a line width of the first line-shaped thin film is W1, a diameter K1 of the at least one first discharge opening is set to be in the range from about 0.1 W1 to about 1.0 W1.

49. The deposition method of claim 27,
wherein if a set value of a line width of the second line-shaped thin film is W2, a diameter K2 of the at least one second discharge opening is set to be in the range from about 0.1 W2 to about 1.0 W2.

50. The deposition method of claim 27,
wherein the first source gas and the second source gas are discharged from the at least one first discharge opening and the at least one second discharge opening at predetermined pressures or flow rates while being mixed with a carrier gas, respectively.

51. The deposition method of claim 27,
wherein the first line-shaped thin film and the second line-shaped thin film are light emitting layers.

52. The deposition method of claim 27,
wherein the first film forming source material and the second film forming source material are organic materials.

53-54. (canceled)

55. An organic EL display manufactured by using a deposition method as claimed in claim 27.

56. A lighting device manufactured by using a deposition method as claimed in claim 27.
